(19) United States
(12) Patent Application Publication
(10) Pub. No.: US 2015/0325817 A1
(43) Pub. Date: Nov. 12, 2015

(54) APPARATUS AND METHOD FOR MANUFACTURING ORGANIC LIGHT EMITTING DIODE DISPLAY

(71) Applicant: Samsung Display Co., Ltd., Yongin-City (KR)

(72) Inventor: Jang Sub KIM, Suwon-si (KR)

(21) Appl. No.: 14/493,840

(22) Filed: Sep. 23, 2014

(30) Foreign Application Priority Data
May 8, 2014 (KR) 10-2014-0054866

(51) Int. Cl. H01L 51/56; B05C 11/10; H01L 51/00

(52) U.S. Cl. CPC H01L 51/56; H01L 51/0005; B05C 11/10

(57) ABSTRACT

An apparatus for manufacturing an organic light emitting diode display and a method for manufacturing an organic light emitting diode display using the same. The apparatus for manufacturing an organic light emitting diode display includes: a chamber; a stage which is disposed inside the chamber and on which an array substrate is seated; and a source portion to evaporate a first solvent in the chamber, such that the solvent condenses on the array substrate.

### CROSS-REFERENCE TO RELATED APPLICATION

This application claims priority from and the benefit of Korean Patent Application No. 10-2014-0054866, filed on May 8, 2014, which is hereby incorporated by reference for all purposes as if fully set forth herein.

### BACKGROUND

1. Field

Exemplary embodiments relate to an apparatus for manufacturing an organic light emitting diode display and a method for manufacturing an organic light emitting diode display using the same.

2. Discussion of the Background

A display device that implements various pieces of information on a screen is one of the core technologies of the information and communication generation, and has been developed in the direction in which the display device becomes thinner, lighter, and portable, and has high performance. Accordingly, a flat display device, such as an organic light emitting display has been under the spotlight to reduce the weight and volume of the display device, and resolve the drawbacks of a cathode ray tube (CRT). Organic light emitting diode displays are self-luminous device using a thin organic light emitting layer interposed between electrodes, and has the advantage that the thin filming thereof becomes possible similar to paper. Organic light emitting diode displays are classified as small-molecule and polymer organic light emitting diode displays, depending on materials of the organic light emitting layer that generates light. The organic light emitting layer of the small-molecule organic light emitting diode display is generally a thin film formed by vacuum deposition, and the organic light emitting layer of the polymer organic light emitting diode display is generally a thin film formed using a liquid coating method, such as spin coating or ink jet printing.

In the case of forming the organic light emitting layer through the ink jet printing method, the organic light emitting layer is formed in a manner where an organic light emitting ink that includes an organic light emitting material and a solvent is discharged from an ink jet print head onto at least one pixel of a display region of a substrate, and then the discharged organic light emitting ink is dried. Here, drying of the organic light emitting ink may mean evaporation of the solvent included in the organic light emitting ink. In general, the solvent that has high volatility is volatilized in a short time after the organic light emitting ink is discharged, and thus, the organic light emitting ink is dried. In this case, the concentration of molecules of the evaporated solvent (hereinafter, referred to as “evaporated solvent molecules”) becomes high is in the center portion of a region where the organic light emitting ink is discharged, whereas the concentration of the evaporated solvent molecules becomes low at an edge of the region where the organic light emitting ink is discharged, i.e., in the boundary portion between the region where the organic light emitting ink is discharged and a region where the organic light emitting ink is not discharged. If the concentration gradient of the evaporated solvent molecules on the substrate becomes non-uniform as described above, the evaporated solvent molecules may be diffused from the center portion of the region where the organic light emitting ink is discharged to the edge of the region where the organic light emitting ink is discharged, and the edge of the region may be dried relatively faster than the center portion, resulting in a sloped organic light emitting layer in a pixel positioned at the edge of the region where the organic light emitting ink to be discharged. That is, the thickness of the organic light emitting layer of the pixel positioned at the edge of the region where the organic light emitting ink is discharged becomes non-uniform, and this may directly exert an influence on the display quality of the organic light emitting display device.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide an apparatus and method for manufacturing an organic light emitting diode display in which the thickness of an organic layer that is arranged on one pixel is uniform.

According to an exemplary embodiment of the present invention, an apparatus for manufacturing an organic light emitting diode display includes a chamber; a stage disposed inside the chamber and on which an array substrate is seated; and a source portion configured to evaporate a first solvent, such that the evaporated first solvent is condensed on the array substrate.

According to an exemplary embodiment of the present invention, there is provided a method for manufacturing an organic light emitting diode display comprising: evaporating a first solvent in a chamber in which an array substrate is disposed, the array substrate comprising an organic layer disposed on a portion of a pixel electrode exposed through a pixel-defining film; exposing of the array substrate to the evaporated first solvent, to at least partially dissolve the organic layer; and evaporating the first solvent from the organic layer.

The effects according to the present invention are not limited to the contents as exemplified above, but further various effects are included in the description.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the exemplary embodiment of the present invention and are incorporated in and constitute a part of this specification, illustrate exemplary embodiments of the present invention, and, together with the description, serve to explain the principles of the invention.

The above and other objects, features and advantages of the present invention will be more apparent from the following detailed description taken in conjunction with the accompanying drawings, in which:

FIG. 1 is a transparent perspective view of an apparatus for manufacturing an organic light emitting diode display according to an exemplary embodiment of the present invention.

FIG. 2 is a cross-sectional view of the apparatus for manufacturing an organic light emitting diode display of FIG. 1.

FIG. 3 is a partial plan view of an array substrate of FIG. 1.

FIG. 4 is a cross-sectional view cut along line I-I′ of FIG. 3.

FIG. 5A is a partial cross-sectional view of an organic light emitting diode display according to an exemplary embodiment of the present invention.

FIG. 5B is a partial enlarged view of FIG. 5A;

FIG. 6A is a partial cross-sectional view of an organic light emitting diode display according to an exemplary embodiment of the present invention.

FIG. 6B is a partial enlarged view of FIG. 6A.

FIG. 7A is a partial cross-sectional view of an organic light emitting diode display according to an exemplary embodiment of the present invention.

FIG. 7B is a partial enlarged view of FIG. 7A.

FIG. 8 is a perspective view of an apparatus for manufacturing an organic light emitting diode display according to an exemplary embodiment of the present invention.

FIG. 9 is a perspective view of an apparatus for manufacturing an organic light emitting diode display according to an exemplary embodiment of the present invention.

FIG. 10 is a perspective view of an apparatus for manufacturing an organic light emitting diode display according to an exemplary embodiment of the present invention.

FIG. 11 is a perspective view of an apparatus for manufacturing an organic light emitting diode display according to an exemplary embodiment of the present invention.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

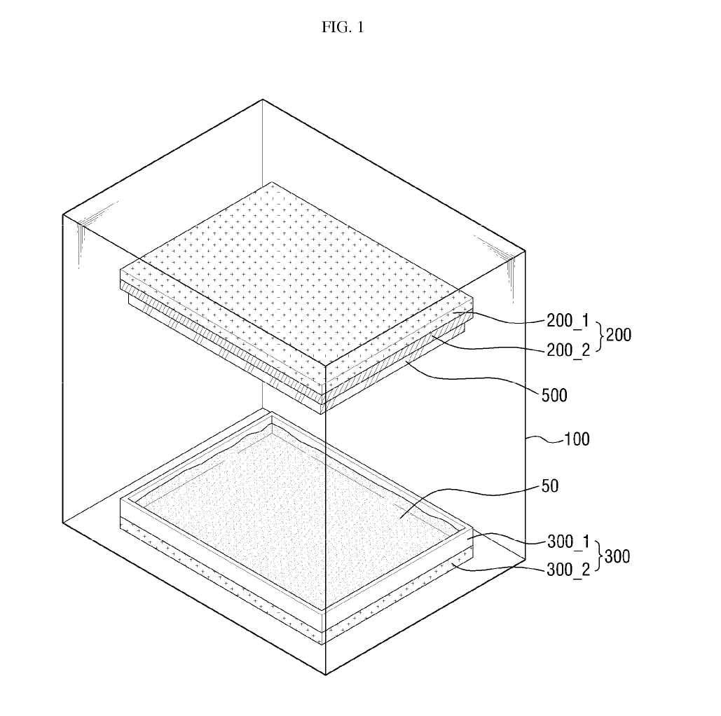

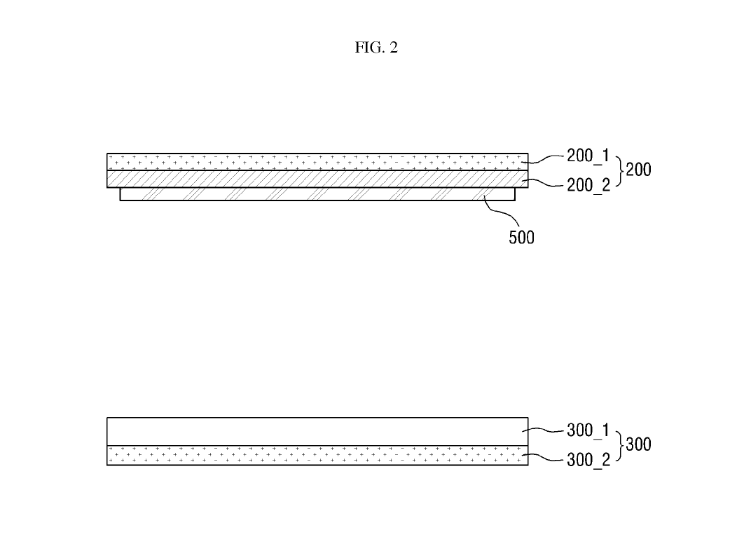

FIG. 1 is a transparent perspective view of an apparatus for manufacturing an organic light emitting diode display according to an exemplary embodiment of the present invention, and FIG. 2 is a cross-sectional view of the apparatus for manufacturing an organic light emitting diode display of FIG. 1.

Referring to FIG. 1, the apparatus for manufacturing an organic light emitting diode display includes a chamber 100, a stage 200 which is arranged inside the chamber 100 and on which an array substrate 500 is seated, and a source portion 300 defining space for an atmosphere of a first solvent 50 in the chamber 100.

The chamber 100 may serve to provide a space in which various elements to be described later are arranged. That is, the chamber 100 may include an internal space that is distinguished from an external space, and the internal space of the chamber 100 may be a space that is isolated from the external space. The inside of the chamber 100 may be airtight.

FIG. 1 exemplifies an exemplary embodiment where the chamber 100 is in a prismatic shape, but the shape of the chamber 100 is not limited thereto.

In an exemplary embodiment, the chamber 100 may be formed to include a metal material, but is not limited thereto. The chamber 100 may be formed using an appropriate material selected in consideration of durability.

The stage 200 may be arranged inside the chamber 100. The stage 200 may be in a plate shape, and may be fixed to the inside of the chamber 100, but is not limited thereto. The stage 200 may move upward and downward, or may be transported from the outside to the inside of the chamber 100.

The array substrate 500 to be described in more detail later may be seated on the stage 200. A fixing element (not illustrated) to fix the array substrate 500 may be provided on the stage 200. The fixing element may be any device suitable for fixing the array substrate 500 on the stage 200.

In an exemplary embodiment, the stage 200 may include a seat portion 200_1 on which the array substrate 500 is seated, and a first temperature adjustment portion 200_2 to heat the array substrate 500 arranged on the stage 200.

The seat portion 200_1 may come in direct contact with the array substrate 500 to fix the array substrate 500. In an exemplary embodiment, the seat portion 200_1 may be fixed to the array substrate 500 through vacuum adhesion, but the method in which the seat portion 200_1 fixes the array substrate 500 is not limited thereto.

The seat portion 200_1 may be in a rectangular plate shape to correspond to the shape of the array substrate 500. However, this is merely exemplary, and the shape of the seat portion 200_1 is not limited thereto. For example, the seat portion 200_1 may be in a circular plate shape or in a plane shape that includes a curve at least partly to correspond to the shape of the array substrate 500.

The seat portion 200_1 may include a metal material at least partly, but the material of the seat portion 200_1 is not limited thereto.

The first temperature adjustment portion 200_2 may serve to adjust the temperature of the array substrate 500. Exemplarily, the first temperature adjustment portion 200_2 may apply heat to the array substrate 500 through heat conduction, but the heat transfer method is not limited thereto.

If the first temperature adjustment portion 200_2 applies heat to the array substrate 500, the organic layer that is arranged on the array substrate 500 may be easily dissolved. This will be described in detail later.

A source portion may create a first solvent atmosphere in the chamber 100. The first solvent may be a solvent that can dissolve the organic layer formed on the array substrate 500 to be described later. The type of the first solvent is not limited, and the first solvent may be selected to correspond to the type of the organic layer formed on the array substrate 500.

In an exemplary embodiment, the source portion 300 may be arranged in the internal space of the chamber 100. However, this is merely exemplary, and the position of the source portion 300 is not limited thereto. The source portion 300 may be arranged to communicate with the outside and the inside of the chamber 100.

In an exemplary embodiment, the source portion 300 may be arranged inside the chamber 100. Specifically, the source portion 300 may include a storage tank 300_1 arranged in the chamber 100 to store the first solvent 50, and a second temperature adjustment portion 300_2 that applies heat to the storage tank 300_1.

The storage tank 300_1 may include a space that is partitioned by a side wall, and may have one open surface. That is, the remaining portion except for the one open surface of the storage tank 300_1 may be closed by the side wall, and thus, the first liquefied solvent may be stored in the storage tank 300_1.

In an exemplary embodiment, the storage tank 300_1 may be in a prismatic shape with one open surface. However, this is exemplary, and the shape of the storage tank 300_1 is not limited thereto. That is, the storage tank 300_1 may be formed to have all kinds of structures that can store the first liquefied solvent 50 irrespective of its shape.

The second temperature adjustment portion 300_2 may adjust the temperature of the storage tank 300_1. Specifically, the second temperature adjustment portion 300_2 may heat the first solvent 50 stored in the storage tank 300_1. That is, the second temperature adjustment portion 300_2 may accelerate the evaporation of the first solvent 50 through heating of the first solvent 50. The second temperature adjustment portion 300_2 may adjust the speed to form the first solvent atmosphere in the chamber 100 through adjustment of the temperature of the first solvent 50.

FIGS. 1 and 2 exemplify a case where the second temperature adjustment portion 300_2 is arranged on the lower side of the storage tank 300 1, but the position of the second temperature adjustment portion 300_2 is not limited thereto. That is, the second temperature adjustment portion 300_2 may be understood as a configuration that includes all suitable methods for adjusting the temperature of the storage tank 300_1 irrespective of its detailed arrangement.

In an exemplary embodiment, the stage 200 and the source portion 300 may face each other. That is, the seat portion 200_2 of the stage 200 may look downward, and the open surface of the storage tank 300_1 may face upward. In other words, the array substrate 500 that is seated on the seat portion 200_2 may face downward, and the open surface of the storage tank 300_1 may face upward. However, this is merely exemplary, and the positions of the array substrate 500 and the open surface of the storage tank 300_1 are not limited thereto. For example, in an exemplary embodiment, the array substrate 500 may be arranged to face upward and the open surface of the storage tank 300_1 may also be arranged to face upward. Under such arrangement, if the first solvent atmosphere is formed in the chamber 100, in the same manner as described above, the organic layer on the array substrate can be dissolved. That is, the scope of the present invention is not limited to the spatial arrangement relationship between the stage 200_1 and the source portion 300_1.

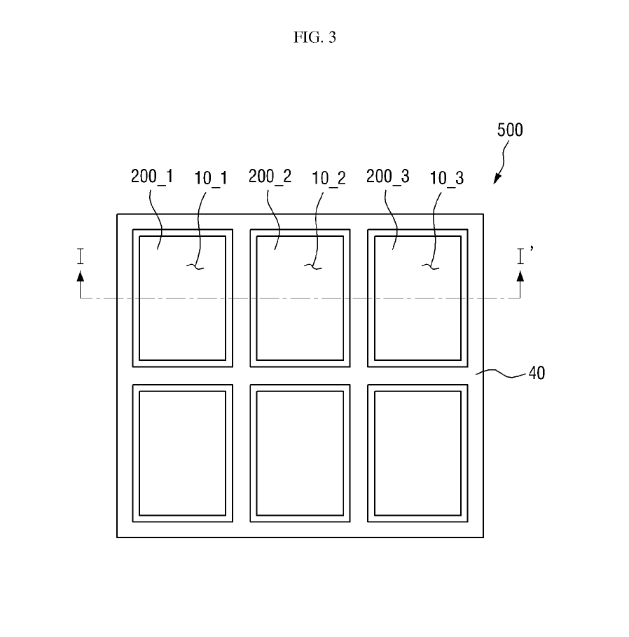

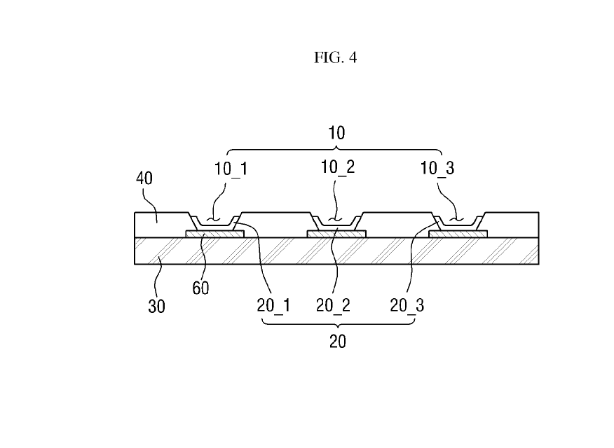

As described above, the array substrate 500 may be seated on the stage 200. The array substrate 500 will be described in detail with reference to FIGS. 3 and 4.

FIG. 3 is a partial plan view of an array substrate 500 of FIG. 1, and FIG. 4 is a cross-sectional view cut along line I-I′ of FIG. 3.

Referring to FIGS. 3 and 4, the array substrate 500 according to an exemplary embodiment of the present invention, may include a substrate 30, a first electrode 60 formed on the substrate 30, a pixel-defining layer 40 at least partly exposing the first electrode 60, and an organic layer 20 covering the first electrode 60 that is exposed by the pixel-defining layer 40.

The substrate 30 may be a unit display substrate, or a mother substrate before it is cut to be divided into a plurality of unit display substrates. The substrate 30 may be one sheet of substrate or may include a plurality of laminated substrates.

The substrate 30 may include an insulating substrate. The insulating substrate may be formed of a transparent glass material having SiO₂ as a main component. In some embodiments, the substrate 30 may be made of an opaque material or a plastic material. Further, the substrate 30 may be a flexible substrate that can be bent, folded, or rolled.

Although not illustrated in the drawing, the substrate 30 may further include other structures formed on the insulating substrate. Examples of the other structures include a wiring, an electrode, and an insulating layer. If the organic light emitting diode display is an active organic light emitting display device, the substrate 30 may include a plurality of thin film transistors (not illustrated) formed on the substrate 30. The thin film transistor may include a gate electrode (not illustrated), a source electrode (not illustrated), a drain electrode (not illustrated), and a semiconductor layer (not illustrated) that includes a channel region. The semiconductor layer may be formed of amorphous silicon, polycrystalline silicon, or monocrystalline silicon. In an exemplary embodiment, the semiconductor layer may be made of a semiconductor oxide. The drain electrode of at least a part of the plurality of thin film transistors may be electrically connected to the first electrode 60.

The first electrode 60 may be positioned on the substrate 10. The first electrode 60 may be formed to be spaced apart from each other. The first electrode 60 may be an anode electrode. If the first electrode 60 is used as the anode electrode, the first electrode 60 may be made of a conductive material having a high work function. If the organic light emitting diode display is a bottom emission type display device, the first electrode 60 may be formed of a material, such as ITO, IZO, ZnO, or In₂O₃, or a laminated layer thereof. If the organic light emitting diode display is a top emission type display device, the first electrode 60 may further include a reflective layer that is formed of Ag, Mg, Al, Pt, Pd, Au, Ni, Nd, Ir, Cr, Li, or Ca. The first electrode may be variously modified to have a structure of two or more layers using at least two different materials as described above.

The pixel-defining layer 40 may be formed on the first electrode 60. The pixel-defining layer 40 may expose the first electrode 60 at least partly. That is, in an exemplary embodiment, the pixel-defining layer 40 may partly expose the first electrode 60 or may completely expose the first electrode 60. In the case where the pixel-defining layer 40 completely exposes the first electrode 60, the first electrode 60 may be arranged to be spaced apart from the pixel-defining layer 40 by a predetermined distance. The pixel-defining layer may include at least one organic material selected from the group including benzocyclobutene (BCB), polyimide (PI), polyamide (PA), acrylic resin, and phenol resin, or may include an inorganic material, such as silicon nitride. The pixel-defining layer 40 may also be made of a photosensitive material including black pigment, and in this case, the pixel-defining layer 40 may serve as a light blocking member.

The organic layer 20 may be positioned on the first electrode 60. The organic layer 20 may include organic material layers included in the organic light emitting diode display, i.e., an organic light emitting layer (EML), a hole injection layer (HIL), a hole transport layer (HTL), an electron injection layer (EIL), and an electron transport layer ETL). The organic layer 20 may have a single layer structure including one selected from the organic material layers, or may have a multilayer structure including two or more of the organic material layers.

In an exemplary embodiment, the organic layer 20 may include a first organic layer 20_1, a second organic layer 20_2, and a third organic layer 20_3. The first to third organic layers may include different organic materials to emit red light, green light, and blue light, but are not limited thereto. Hereinafter, the organic layer 20 may be understood as at least one of the first organic layer 20_1, the second organic layer 20_2, and/or the third organic layer 20_3.

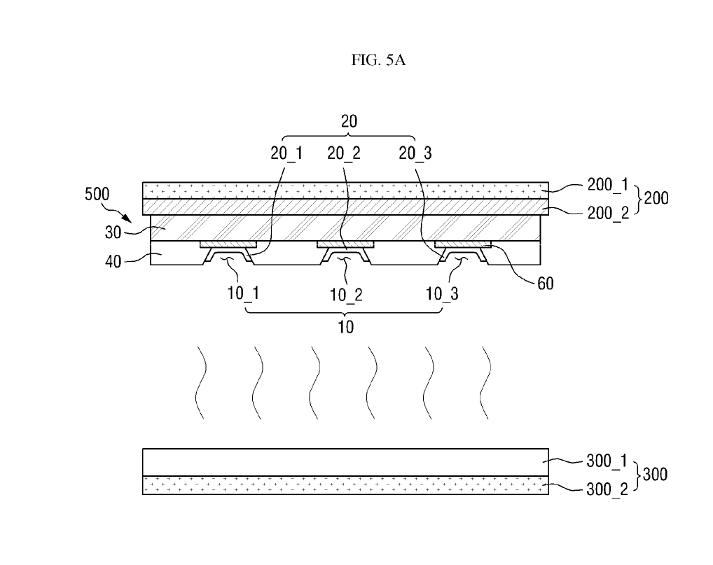

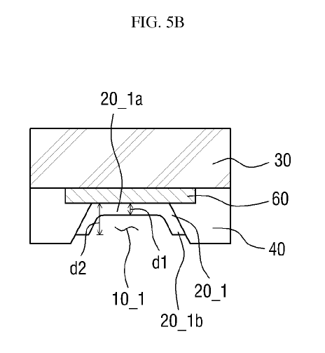

As illustrated in FIG. 5B, the organic layer 20 may include a center portion 20_1a and an edge portion 20_1b. In accordance with the drying characteristics of organic materials that form the organic layer 20, the thickness of the center portion 20_1a may be smaller than the thickness of the edge portion 20_1b. As the thicknesses of the center portion 20_1a and the edge portion 20_1b of the organic layer 20 become more uniform, the display performance can be improved. The details of the center portion 20_1a and the edge portion 20_1b of the organic layer will be described later.

A plurality of pixels 10 may be defined on the array substrate 500 by the pixel-defining layer 40. As illustrated in FIG. 3, in an exemplary embodiment, the pixel 10 may include a first pixel 10_1, a second pixel 10_2, and a third pixel 10_3. The first pixel 10_1, the second pixel 10_2, and the third pixel 10_3 may correspond to the first organic layer 20_1, the second organic layer 20_2, and the third organic layer 20_3.

Hereinafter, referring to FIGS. 5A to 7B, a method for manufacturing an organic light emitting diode display according to an exemplary embodiment of the present invention will be described.

FIG. 5A is a partial cross-sectional view of an organic light emitting diode display according to an exemplary embodiment of the present invention, and FIG. 5B is a partial enlarged view of FIG. 5A.

Referring to FIGS. 5A and 5B, an array substrate 500, which includes a substrate 30, a first electrode 60 formed on the substrate 30, a pixel-defining layer 40 exposing the first electrode 60 at least partly, and an organic layer 20 covering the first electrode 60 that is exposed by the pixel-defining layer 40, may be arranged in a chamber 100 (as shown in FIG. 1) in a state where the array substrate 500 is seated on a stage 200.

As described above, the source portion 300 may create a first solvent atmosphere in the chamber 100. In other words, a first solvent in a gaseous state that is evaporated from the source portion 300 may fill the inside of the chamber 100. The first solvent in the gaseous state may come in contact with the organic layer 20 to be condensed. That is, as described above, the first solvent may be a solvent having dissolution ability that can dissolve the organic layer 20, and if the first solvent as described above comes in contact with the organic layer 20, it can dissolve the organic layer 20 at least partly.

As described above, the organic layer 20 may include a center portion 20_1a and an edge portion 20_1b. FIG. 5B exemplifies the first pixel 10_1, but the remaining pixels may be substantially the same as the first pixel 10_1. The edge portion 20_1b of the organic layer 20 may be a portion that is adjacent to the first electrode 60 and the pixel-defining layer 40, and the center portion 20_1a may mean the remaining portion of the organic layer 20 except for the edge portion 20_1b.

The organic layer 20 of the array substrate 500 may be formed through drying of an organic material. Due to the drying characteristics, the thickness d2 of the edge portion 20_1b may be relatively larger than the thickness d1 of the center portion 20_1a. The non-uniformity in thickness of the organic layer 20 may cause inferiority of the display performance.

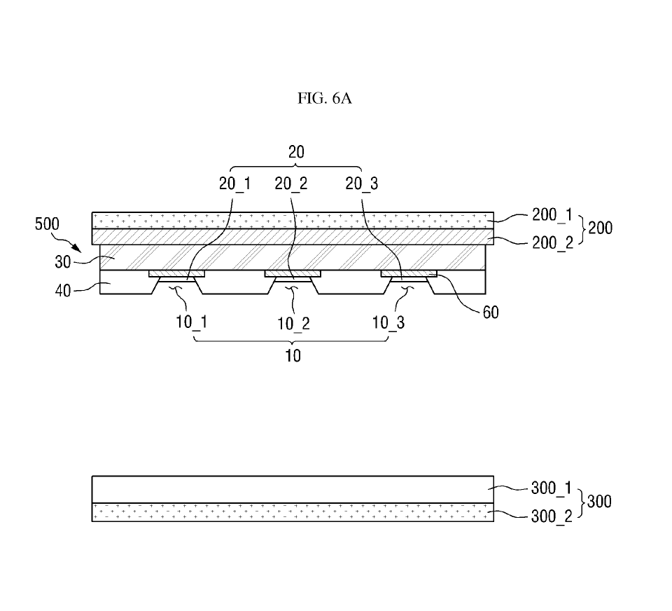

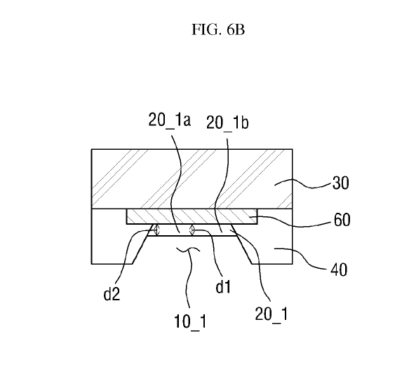

FIG. 6A is a partial cross-sectional view of an organic light emitting diode display according to the exemplary embodiment of the present invention, and FIG. 6B is a partial enlarged view of FIG. 6A.

Referring to FIGS. 6A and 6B, the organic layer 20 of the array substrate 500 may be at least partly in a liquefied state. As described above, if the organic layer 20 is exposed under the first solvent atmosphere, the organic layer 20 may be dissolved at least partly. The dissolved organic layer 20 may be at least partly liquefied, and in this state, there may be less difference between the thickness d2 of the edge portion 20_1b and the thickness d1 of the center portion 20_1 or the thickness of the edge portion 20_1b may be substantially equal to the thickness of the center portion 20_1a.

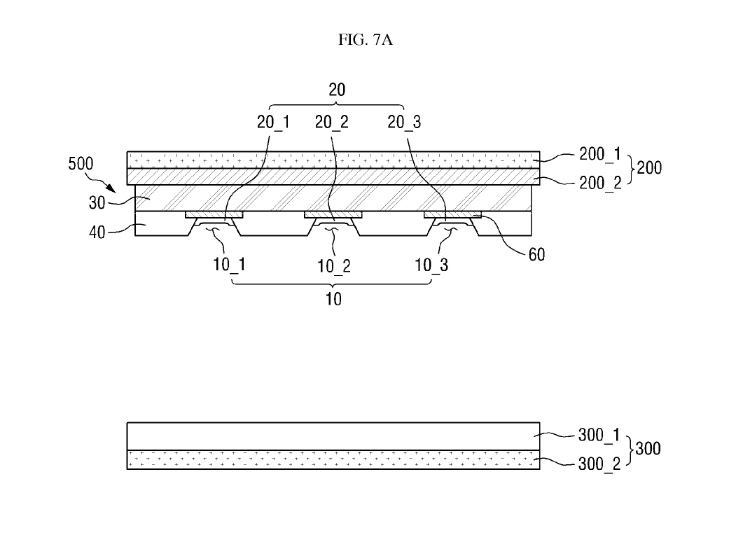

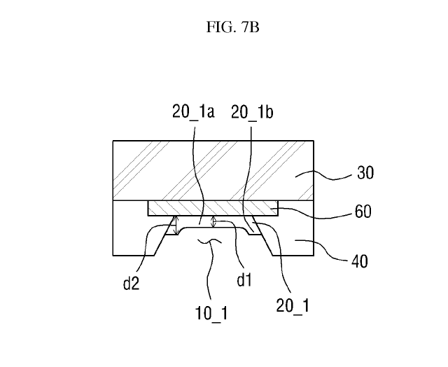

FIG. 7A is a partial cross-sectional view of an organic light emitting diode display according to an exemplary embodiment of the present invention, and FIG. 7B is a partial enlarged view of FIG. 7A.

Referring to FIGS. 7A and 7B, the organic layer that is at least partly dissolved may be re-dried.

FIG. 7A exemplifies a case where drying may be performed within the chamber 100 (as shown in FIG. 1), but is not limited thereto. The re-drying may be performed in the inside of the chamber 100 or on the outside of the chamber 100.

In the case where the organic layer 20 that is formed as described above is dissolved at least partly and then is re-dried, the thickness profile of the organic layer 20 may be improved. In other words, the organic layer 20 may reduce the difference between the thickness d2 of the edge portion 20_1b and the thickness d1 of the center portion 20_1a. That is, according to the apparatus for manufacturing an organic light emitting diode display according to an embodiment of the present invention, the following effects may be obtained.

First, as seen from the pixel unit, the organic layer 20 that is arranged on one pixel can be formed with uniform thickness. Second, as seen from the side surface of the whole array substrate, the organic layer arranged on one portion of the pixel and the organic layer arranged on the other portion of the pixel can be formed with a relatively uniform thickness. That is, depending on the organic layer forming method in the organic layer forming procedure, the thickness of the organic layer may differ by portions, and by dissolving the array substrate 500 on which the organic layer is formed as described above at least partly, and then re-drying the array substrate 500, the whole organic layer 20 of the array substrate 500 can be formed with a relatively uniform thickness.

Hereinafter, an apparatus for manufacturing an organic light emitting diode display according to an exemplary embodiment of the present invention will be described. In the following embodiment, the same reference numerals are given to the same configurations as the above-described configurations, and the duplicate description thereof will be omitted or simplified.

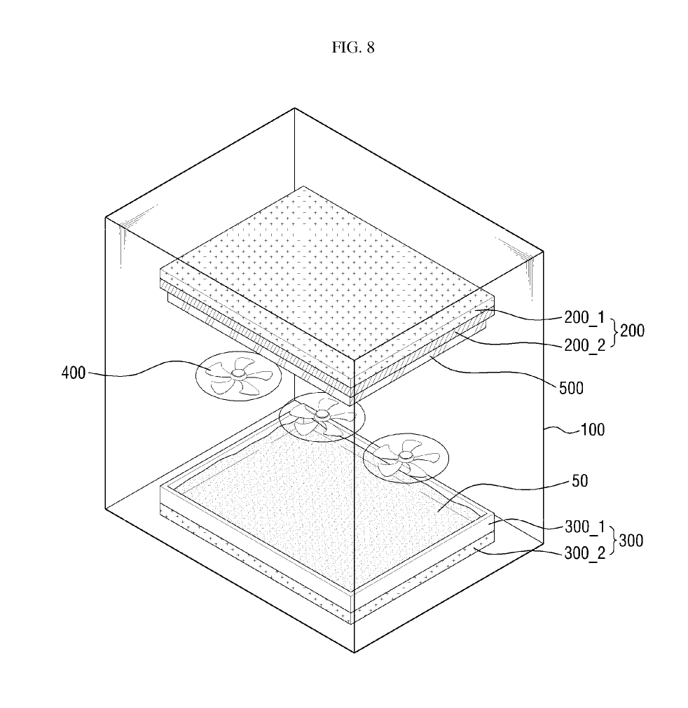

FIG. 8 is a perspective view of an apparatus for manufacturing an organic light emitting diode display according to an exemplary embodiment of the present invention.

Referring to FIG. 8, an apparatus for manufacturing an organic light emitting diode display according to an exemplary embodiment of the present invention is different from the apparatus according to the embodiment of FIG. 1, by further including circulation fans arranged in the chamber.

In an exemplary embodiment, the apparatus for manufacturing an organic light emitting diode display according to an exemplary embodiment of the present invention may further include the circulation fans 400. In the case where the circulation fans 400 are arranged in the chamber 100, an air is circulated in the chamber 100 to expedite the creation of the first solvent atmosphere.

FIG. 8 exemplifies a case where three circulation fans 400 are arranged. However, this is exemplary, and the scope of the present invention is not limited by the number of circulation fans 400.

In an exemplary embodiment, the circulation fans 400 may be arranged between the stage 200 and the source portion 300. If the circulation fans 400 are arranged between the stage 200 and the source portion 300 as described above, the first solvent in a gaseous state, which comes from the source portion 300, can be transferred to the array substrate 500 that is seated on the stage 200 more effectively.

However, since the circulation fans 400 are to expedite the creation of the first solvent atmosphere through circulation of the air in the chamber 100 as described above, the positions thereof are not limited thereto.

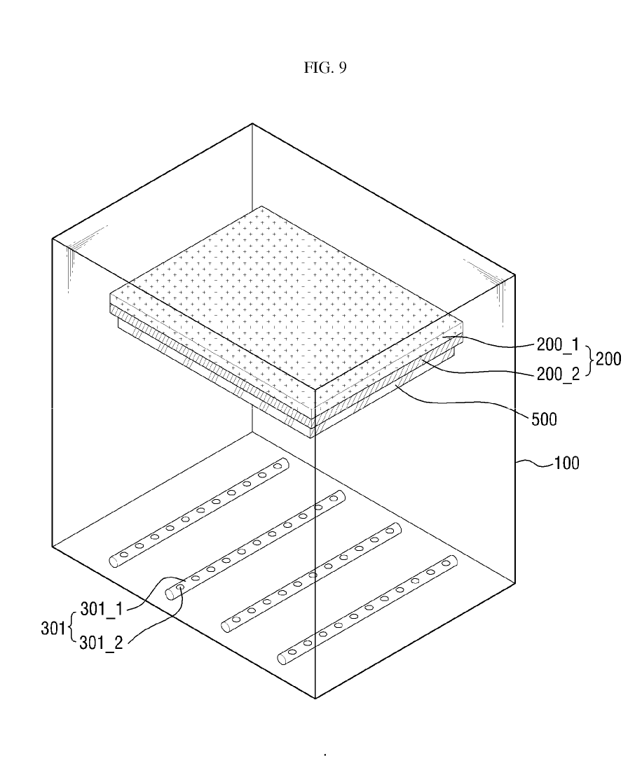

FIG. 9 is a perspective view of an apparatus for manufacturing an organic light emitting diode display according to an exemplary embodiment of the present invention.

Referring to FIG. 9, an apparatus for manufacturing an organic light emitting diode display according to an exemplary embodiment of the present invention is different from the apparatus according to the embodiment of FIG. 1 that a source portion 301 includes a straight type pipe 301_1 that extends in a first direction and injection holes 301_2 formed on the pipe 301_1.

In an exemplary embodiment, the source portion 301 includes the straight type pipe 301_1 that extends in the first direction and the injection holes 301_2 formed on the pipe 301_1. In the internal space of the straight type pipe 301_1, the first solvent 50 (as shown in FIG. 8) may flow, and the first solvent 50 may be stored in a separate storage space arranged inside or outside of the chamber 100. That is, the separate storage space and the straight type pipe 301_1 may communicate with each other, and through this, the first solvent 50 may be circulated in the straight type pipe 301_1. If the first solvent 50 is circulated in the straight type pipe 301_1, it may be discharged out of the straight type pipe 301_1 through the injection holes 301_2. As described above, by the first solvent 50 that is discharged through the injection holes 301_2, the first solvent atmosphere may be created inside the chamber 100.

In an exemplary embodiment, the source portion 301 may include the plurality of pipes 301_1, and the respective pipes 301_1 may be arranged in parallel to each other.

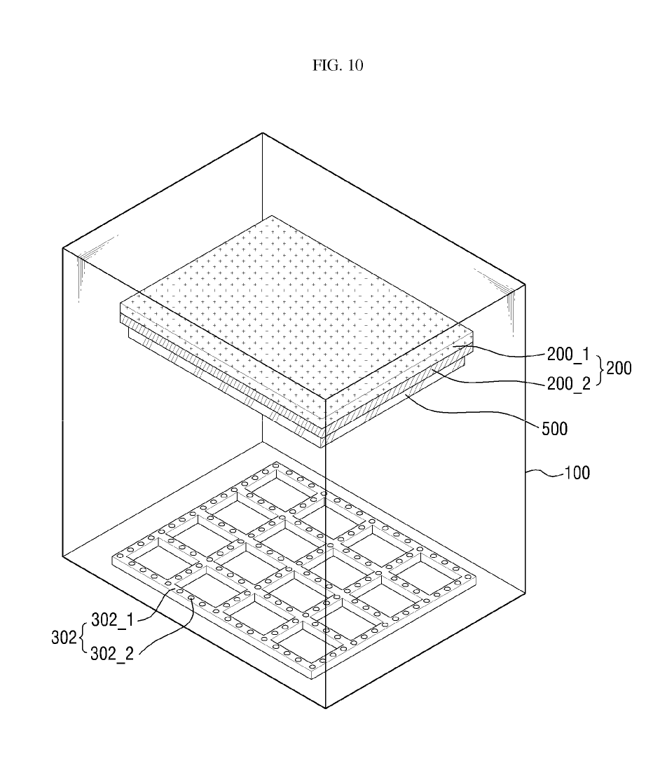

FIG. 10 is a perspective view of an apparatus for manufacturing an organic light emitting diode display according to an exemplary embodiment of the present invention.

Referring to FIG. 10, an apparatus for manufacturing an organic light emitting diode display according to an exemplary embodiment of the present invention is different from the apparatus according to the embodiment of FIG. 9 that a source portion 302 includes a lattice-shaped pipe 302_1 and injection holes 302_2.

For convenience in explanation, the lattice-shaped pipe 302_1 is called a lattice type pipe.

In the internal space of the lattice type pipe 302 1, the first solvent 50 (as shown in FIG. 8) may flow, and the first solvent 50 may be stored in a separate storage space arranged inside or outside of the chamber 100. That is, the separate storage space and the lattice type pipe 302_1 may communicate with each other, and through this, the first solvent 50 may be circulated in the lattice type pipe 302_1. If the first solvent 50 is circulated in the lattice type pipe 302_1, it may be discharged out of the lattice type pipe 302_1 through the injection holes 302_2. As described above, by the first solvent 50 that is discharged through the injection holes 302_2, the first solvent atmosphere may be created inside the chamber 100.

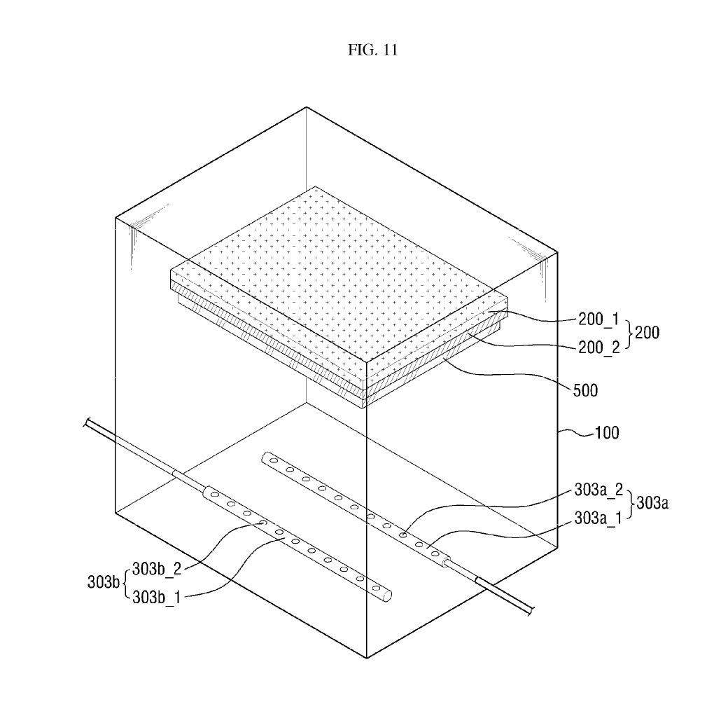

FIG. 11 is a perspective view of an apparatus for manufacturing an organic light emitting diode display according to an exemplary embodiment of the present invention.

Referring to FIG. 11, an apparatus for manufacturing an organic light emitting diode display according to an exemplary embodiment of the present invention is different from the apparatus according to the embodiment of FIG. 1 on the point that a source portion 303 includes a first source portion 303a creating the first solvent atmosphere and a second source portion 303b creating a second solvent atmosphere.

In an exemplary embodiment, the source portion 303 may include the first source portion 303a and the second source portion 303b that discharge two different kinds of solvents. FIG. 11 exemplifies a case where two kinds of solvents are provided, but the number of solvents is not limited. If needed, three or more source portions may be used.

Exemplarily, the first source portion 303a and the second source portion 303b may include straight pipes 303a_1 and 303b_1 and injection holes 303a_2 and 303b_2. However, this is exemplary, and as in the case of FIG. 10, the first source portion 303a and the second source portion 303b may include lattice type pipes. Further, the first source portion 303a and the second source portion 303b may be connected to different solvent storage spaces. That is, the first source portion 303a may communicate with the space for storing the first solvent, and the second source portion 303b may communicate with the space for storing the second solvent.

The second solvent may be a solvent that is different from the first solvent. As described above, the kind of the second solvent is not limited, and the second solvent may be selected to correspond to the kind of the organic layer of the array substrate 500.

In the case where the source portion 303 includes the first source portion 303a and the second source portion 303b, three different kinds of atmospheres may be mixed in the chamber 100. That is, by controlling the first source portion 303a and the second source portion 303b, the first solvent atmosphere, the second solvent atmosphere, and an atmosphere in which the first solvent and the second solvent are mixed may be created.

As described above, the first solvent and the second solvent may differ depending on the kind of the organic layer of the array substrate 500. That is, by selecting appropriate first solvent and second solvent, the degree of dissolution of the organic layer can be adjusted, and through this, the thickness uniformity of the organic layer can be secured more efficiently.

Hereinafter, a method for manufacturing an organic light emitting diode display according to an exemplary embodiment of the present invention will be described.

The method for manufacturing an organic light emitting diode display according to an embodiment of the present invention may include preparing an array substrate 500 which includes a substrate 30, a first electrode 60 formed on the substrate 30, a pixel-defining layer 40 exposing the first electrode 60 at least partly, and an organic layer 20 covering the first electrode 60 that is exposed by the pixel-defining layer 40; dissolving the organic layer 20 at least partly through arrangement of a first solvent atmosphere; and re-drying the at least partly dissolved organic layer 20.

First, preparing the array substrate 500, which includes the substrate 30, the first electrode 60 formed on the substrate 30, the pixel-defining layer 40 exposing the first electrode 60 at least partly, and the organic layer 20 covering the first electrode 60 that is exposed by the pixel-defining layer 40, is performed. The array substrate 500 may be substantially the same as the array substrate 500 as described above with reference to FIG. 4, and thus the detailed description thereof will be omitted.

Then, dissolving of the organic layer 20 at least partly may be performed through arrangement of the array substrate 500 under the first solvent atmosphere. The dissolving of the organic layer 20 at least partly through arrangement of the array substrate 500 under the first solvent atmosphere may be performed by the apparatus for manufacturing the organic light emitting diode display according to exemplary embodiments of the present invention, but is not limited thereto. As described above, the organic layer 20 of the array substrate 500 may be dissolved at least partly under the first solvent atmosphere. If the organic layer 20 is dissolved, the difference between the thickness d2 of the edge portion 20_1b of the organic layer 20 and the thickness d1 of the center portion 20_1a may be reduced, or the thickness d2 of the edge portion 20_1b may be substantially equal to the thickness d1 of the center portion 20_1a.

Then, re-drying of the at least partly dissolved organic layer 20 may be performed. Various types of drying methods may be adopted for re-drying. In the case where the organic layer 20 that is dissolved at least partly is re-dried, the thickness uniformity of the organic layer 20 can be improved in comparison to that before being dissolved and re-dried. That is, as seen from the side surface of the pixel, the edge portion 20_1b of the organic layer and the center portion 20_1a of the organic layer may have uniform thickness, and as seen from the whole side surface of the array substrate, the thickness of the organic layer arranged on the whole region of the array substrate may become uniform.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. An apparatus for manufacturing an organic light emitting diode display, comprising:
a chamber;
a stage disposed inside the chamber and on which an array substrate is seated; and
a source portion configured to evaporate a first solvent, such that the evaporated first solvent is condensed on the array substrate.

2. The apparatus of claim 1, wherein the stage comprises a seat portion on which the array substrate is seated and a first temperature adjustment portion configured to heat the array substrate;

3. The apparatus of claim 2, wherein the seat portion of the stage and the source portion face each other.

4. The apparatus of claim 1, wherein,
the source portion is disposed in the chamber, and
the source portion comprises a storage tank configured to store the first solvent and a second temperature adjustment portion configured to heat the storage tank.

5. The apparatus of claim 1, wherein the array substrate comprises:
a substrate;
a first electrode disposed on the substrate;
a pixel-defining layer disposed on the substrate and through which a portion of the first electrode is exposed; and
an organic layer covering the exposed portion of first electrode.

6. The apparatus of claim 5, wherein the first solvent is evaporated to at least partially dissolve the organic layer.

7. The apparatus of claim 1, further comprising circulation fans arranged in the chamber.

8. The apparatus of claim 1, wherein the source portion comprises at least one pipe comprising injection holes.

9. The apparatus of claim 1, wherein the source portion comprises a lattice type pipe comprising injection holes.

10. The apparatus of claim 1, wherein the source portion comprises:
a first source portion configured to evaporate the first solvent; and
a second source portion configured to evaporate the second solvent.

11. The apparatus of claim 10, wherein the evaporated first and second solvents are mixed within the chamber.

12. A method for manufacturing an organic light emitting diode display comprising:
evaporating a first solvent in a chamber in which an array substrate is disposed, the array substrate comprising an organic layer disposed on a portion of a pixel electrode exposed through a pixel-defining film;
exposing of the array substrate to the evaporated first solvent, to at least partially dissolve the organic layer; and
evaporating the first solvent from the organic layer.

13. The method of claim 12, wherein the first solvent is evaporated from a source portion disposed on the chamber, the source portion comprising:
a storage tank configured to store the first solvent; and
a temperature adjustment portion configured to heat the storage tank.

14. The method of claim 12, further comprising circulation fans disposed in the chamber.

15. The method of claim 12, wherein the source portion comprises at least one pipe comprising injection holes.

16. The method of claim 12, wherein the source portion comprises a lattice type pipe comprising injection holes.

17. The method of claim 12, wherein the source portion comprises pipes that extend parallel to one another.

18. The method of claim 13, wherein a second solvent is evaporated from the source portion, the evaporated first and second solvents being mixed within the chamber.
